(19) United States
(12) Patent Application Publication
(10) Pub. No.: US 2025/0331354 A1
(43) Pub. Date: Oct. 23, 2025

(54) HYBRID ENCAPSULATION FILM AND METHOD OF MANUFACTURING LIGHT-EMITTING DEVICE USING THE SAME

(71) Applicant: Lextar Electronics Corporation, Hsinchu City (TW)

(72) Inventors: Kiet Tuong LY, Hsinchu City (TW); Fu-Hsin CHEN, Hsinchu City (TW); Chun-Min LIN, Hsinchu City (TW)

(21) Appl. No.: 19/070,335

(22) Filed: Mar. 4, 2025

(30) Foreign Application Priority Data
Apr. 23, 2024 (TW) 113115060

(51) Int. Cl. H10H 29/856; H10H 29/01; H10H 29/852

(52) U.S. Cl. CPC H10H 29/856; H10H 29/0362; H10H 29/0363; H10H 29/852

(57) ABSTRACT

A method of manufacturing a light-emitting device includes: providing a substrate, providing a light-emitting structure containing a plurality of solid-state light sources disposed on the substrate, and providing a hybrid encapsulation film for encapsulating the light-emitting structure. The hybrid encapsulation film includes a B-stage light-transmitting layer having a front surface and a back surface and a plurality of first reflective layers disposed at intervals on the front surface of the B-stage light-transmitting layer. The method further includes: laminating the back surface of the B-stage light-transmitting layer of the hybrid encapsulation film toward the solid-state light sources of the light-emitting structure, so that the solid-state light sources are embedded in the B-stage light-transmitting layer and correspond to the positions of the first reflective layers, and performing a thermal process to cure the hybrid encapsulation film.

### CROSS REFERENCE TO RELATED APPLICATIONS

### TECHNICAL FIELD

This Application claims priority of Taiwan Patent Application No. 113115060, filed on Apr. 23, 2024, the content of which is incorporated by reference herein.

### TECHNICAL FIELD

The disclosure relates to packaging technology, and, in particular, to hybrid encapsulation films and a method of manufacturing light-emitting devices using the same.

### BACKGROUND

### Description of the Related Art

The light-emitting diode (LED) is a semiconductor-based light-emitting element capable of converting electrical energy into light. It boasts advantages such as small size, high energy conversion efficiency, a long lifespan, and energy conservation. Consequently, it finds wide application as a light source in various electronic devices.

The chip on board (COB) technology involves directly mounting the LED chip onto the module substrate and then molding each large unit as a whole. However, the existing COB technology has not been entirely satisfactory in every respect.

### SUMMARY

The object of the present disclosure is to provide a method of manufacturing a light-emitting device including: providing a substrate, providing a light-emitting structure containing a plurality of solid-state light sources disposed on the substrate, and providing a hybrid encapsulation film for encapsulating the light-emitting structure. The hybrid encapsulation film includes a B-stage light-transmitting layer having a front surface and a back surface and a plurality of first reflective layers disposed at intervals on the front surface of the B-stage light-transmitting layer. The method further includes laminating the back surface of the B-stage light-transmitting layer of the hybrid encapsulation film toward the solid-state light sources of the light-emitting structure, so that the solid-state light sources are embedded in the B-stage light-transmitting layer and correspond to the positions of the first reflective layers, and performing a thermal process to cure the hybrid encapsulation film.

An embodiment of the present disclosure provides a method of manufacturing a light-emitting device, including: providing a substrate, providing a light-emitting structure comprising a plurality of solid-state light sources disposed on the substrate, and providing a hybrid encapsulation film for encapsulating the light-emitting structure. The hybrid encapsulation film includes a B-stage light-transmitting layer having a front surface and a back surface, a plurality of first reflective layers disposed at intervals on the front surface of the B-stage light-transmitting layer, and a second reflective layer on the back surface of the B-stage light-transmitting layer. The second reflective layer has a plurality of openings corresponding to the positions of the first reflective layers to partially expose the back surface of the B-stage light-transmitting layer. The method further includes aligning the openings of the second reflective layer of the hybrid encapsulation film to the solid-state light sources of the light-emitting structure respectively. The method further includes laminating the exposed back surface of the B-stage light-transmitting layer toward the solid-state light sources, so that the solid-state light sources are embedded in the B-stage light-transmitting layer and respectively correspond to the positions of the first reflective layers, and performing a thermal process to cure the B-stage light-transmitting layer.

An embodiment of the present disclosure provides a hybrid encapsulation film for encapsulating a light-emitting structure. The hybrid encapsulation film includes a B-stage light-transmitting layer having a front surface and a back surface and a plurality of first reflective layers disposed at intervals on the front surface of the B-stage light-transmitting layer. The first reflective layers are in direct contact with the B-stage light-transmitting layer.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIGS. 1-6 respectively illustrate cross-sectional views of various stages of manufacturing a light-emitting device using a hybrid encapsulation film, in accordance with some embodiments.

FIG. 7A illustrates a plan view of a light-emitting device, in accordance with some embodiments.

FIG. 7B illustrates a cross-sectional view of the light-emitting device, of FIG. 7A, taken along line A-A, in accordance with some embodiments.

FIGS. 8-13, including FIGS. 8A and 8B, respectively illustrate cross-sectional views of various stages of manufacturing a light-emitting device using a hybrid encapsulation film with a second reflective layer, in accordance with some other embodiments.

FIGS. 14-18 respectively illustrate cross-sectional views of various stages of manufacturing a light-emitting device using a hybrid encapsulation film, in accordance with some further embodiments, in which a second reflective layer embedded in a B-stage light-transmitting layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms used in the present specification are merely used to describe particular embodiments, and are not intended to limit the inventive concept. An expression used in the singular encompasses the expression of the plural, unless it has a clearly different meaning in the context. In the present specification, it is to be understood that the terms such as “including,” “having,” or “comprising,” etc. are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It should be noted that the following embodiments can replace, recombine, and combine features in several different embodiments to complete other embodiments without departing from the spirit of the present disclosure. The features between the various embodiments can be combined and used arbitrarily as long as they do not violate or conflict the spirit of the present disclosure.

Unless otherwise defined, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or context of the present disclosure, and should not be interpreted in an idealized or overly formal manner unless so defined.

In the existing packaging technology for light-emitting diodes (LEDs), the encapsulant is applied in a dispensing manner, completely covering the substrate and the multiple LEDs thereon. Due to the high fluidity of the encapsulant has, a dam is required around the LEDs to control its coverage. Subsequently, the uneven surface of the encapsulant is planarized through a planarization process to meet the requirement of surface flatness. However, the method of applying a large amount of encapsulant and then removing the excess leads to a high drop rate of the encapsulant and increased costs. In addition, after performing curing the encapsulant with a thermal process, an additional thermal process is necessary to cure the reflective layer. Therefore, there are certain drawbacks associated with the existing packaging technology for LEDs, including high process complexity and long process times, which reduce productivity and thereby decreased product competitiveness.

The present disclosure provides hybrid encapsulation films and a method of manufacturing light-emitting devices using the same. In contrast to the above-mentioned existing LED packaging technologies, the B-stage light-transmitting layer and the first reflective layer provided by the present disclosure are laminated onto the light-emitting structure in the form of a hybrid encapsulation film. Stated another way, the ability to simultaneously apply the encapsulation film (e.g., the B-stage light-transmitting layer) and the reflective layer (e.g., the first reflective layer) simplifies the process and shortens the processing time, thereby increasing productivity and reducing costs. Moreover, the need for a dam around the LEDs is eliminated with the hybrid encapsulation film provided by the present disclosure due to its low fluidity, further simplifying the process and reducing costs. Furthermore, using the hybrid encapsulation film provided by the present disclosure can mitigate the issue of high drop rates of the encapsulant in existing LED packaging technologies, thereby lowering costs.

In accordance with the embodiments of the present disclosure, unless specifically defined, the term “B-stage state” (also known as a pre-cured state or partial-cured state or semi-cured state or a temporarily cured state) means a state in which the encapsulant material is in the B-stage after a soft bake process (e.g., at temperatures ranging from 90° C. to 120° C. for 15 to 25 minutes). In other words, the encapsulant material is solid at room temperature and exhibits reactivity and a certain level of fluidity. The said encapsulant material can further transition into a C-stage state (a fully cured stage state) through an additional baking process (e.g., at temperatures ranging from 130° C. to 170° C. for 2 to 4 hours), referred to as the term “C-stage state”.

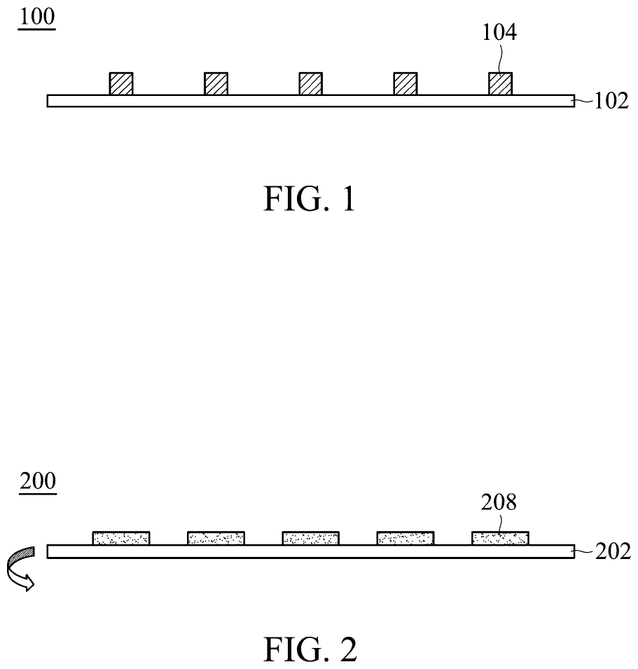

In accordance with the embodiments of the present disclosure, unless specifically defined, the term “B-stage light-transmitting layer” means a film in a B-stage state, and the transmittance thereof is greater than 85% (e.g., greater than 90%) for the light-emitting wavelength of the solid-state light source (e.g., the light-emitting diodes 104 illustrated in FIG. 1).

FIGS. 1-6 respectively illustrate cross-sectional views of various stages of manufacturing a light-emitting device 300 using a hybrid encapsulation film 200, in accordance with some embodiments. It should be understood that additional operations can be provided before, during, and after operations/processes in FIGS. 1-6, and some of the operations described below can be replaced or eliminated for additional embodiments of the method. The order of the operations/processes may be unrestricted and interchangeable.

Referring to FIG. 1, in one embodiment, a substrate 102 and a light-emitting structure 100 are provided, with the light-emitting structure 100 including a plurality of solid-state light sources disposed on the substrate 102. The solid-state light sources may be, for example, a light-emitting diode (LED), a light-emitting diode device, or a chip scale package (CSP) light-emitting diode. In the following disclosure, the solid-state light sources will be exemplified by utilizing the light-emitting diodes 104 to illustrate the embodiments, but the present disclosure is not limited thereto.

In some embodiments, the substrate 102 may be a substrate with conductive circuits, such as a rigid substrate, a flexible substrate, a sapphire substrate, a transparent substrate, an opaque substrate, a silicon substrate, a glass substrate, a printed circuit board (PCB), a metal substrate, a ceramic substrate, or the like, or a combination thereof, but the present disclosure is not limited thereto. The substrate 102 is used to carry electronic components (such as light-emitting diodes 104 and integrated ICs, or the like.) located thereon, and the electronic components are electrically connected to the conductive circuits of the substrate.

In some embodiments, the spacing between each of the light-emitting diodes 104 ranges from 4 mm to 8 mm (e.g., 6 mm). In some embodiments, the light-emitting diodes 104 may be mini LEDs or micro LEDs, but the present disclosure is not limited thereto.

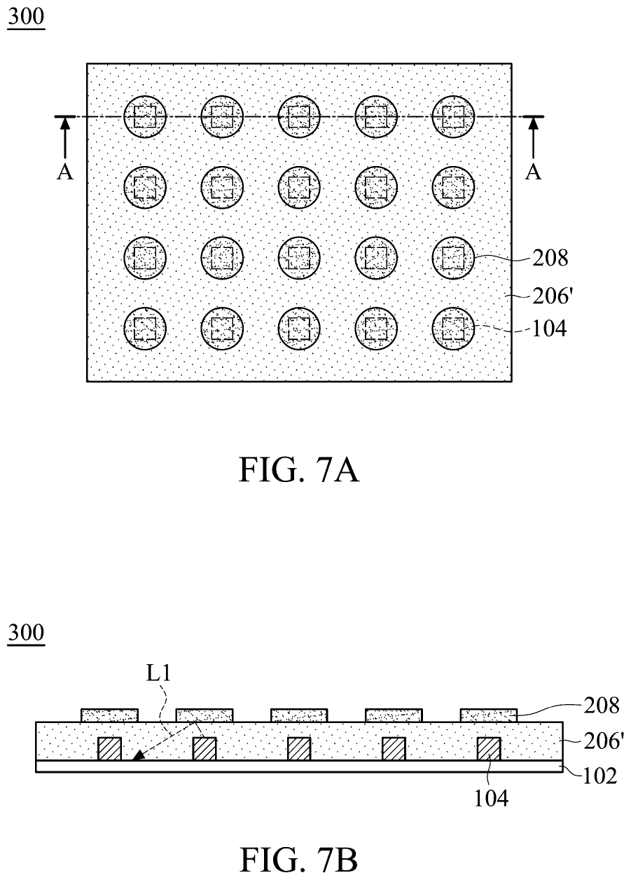

Referring to FIG. 2, in one embodiment, a hybrid encapsulation film 200 is provided for encapsulating a light-emitting structure (e.g., the light-emitting structure 100 depicted in FIG. 1). In one embodiment, a first carrier 202 is provided, with first reflective layers 208 spaced at intervals on it. In some embodiments, the position of the first reflective layers 208 disposed on the first carrier 202 may correspond to the position of the light-emitting diodes 104 disposed on the substrate 102. Consequently, after the hybrid encapsulation film 200 is laminated toward the light-emitting structure 100, the first reflective layers 208 may be positioned above the light-emitting diodes 104, thereby reflecting the light emitted from the light-emitting diodes 104 upward. This reduces the brightness of light emitted upwards from the light-emitting diodes 104, leading to an improvement in the surface light emission uniformity of the light-emitting device 300. Further details will be discussed later, in conjunction with FIG. 7B.

In some embodiments, the first carrier 202 may include a release film, with an anti-adhesive property, which prevents the release film from adhering to the first reflective layers 208. Conversely, the anti-adhesive property also facilitates the removal of the first carrier 202 from the first reflective layers 208 after curing (e.g., the curing processing 320 illustrated in FIG. 6).

In one embodiment, the first reflective layers 208 may include a polymer material doped with reflective particles. In some embodiments, the polymer material may include silicone, epoxy resin, acrylic, or a combination thereof. In some embodiments, the reflective particles may include titanium oxide, aluminum oxide, zirconium oxide, silicon oxide, and other suitable metal oxides. In some embodiments, the reflectivity of the first reflective layers 208 is greater than 90% (e.g., greater than 95%) for the light-emitting wavelength of the light-emitting diodes 104. In some embodiments, the first reflective layers 208 may partially reflect light and partially transmit light. The doping concentration of the reflective particles can be adjusted according to actual requirements.

In some embodiments, the thickness of the first reflective layers 208 is in the range of 40 to 80 μm (e.g., 50 μm), but the present disclosure is not limited thereto. The thickness of the first reflective layers 208 can be adjusted according to requirements. In some embodiments, the area of the first reflective layers 208 is larger than the light area illuminated by the solid-state light sources (e.g., the light-emitting diodes 104) emitting light upwards. Generally, the brightness directly above the light-emitting diodes 104 is relatively higher than on other exiting surfaces, resulting in non-uniformity light emission form the light-emitting device 300. The first reflective layers 208 positioned above the light-emitting diodes 104 can diminish the brightness of the light emitted from the top surface of the light-emitting diodes 104, thereby improving light uniformity of the light-emitting device 300.

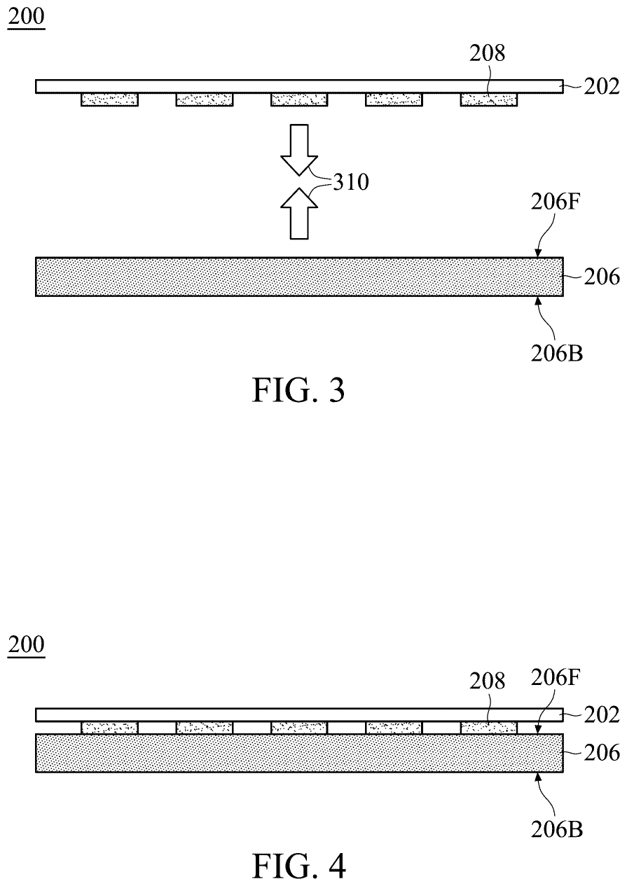

In one embodiment, the first reflective layers 208 may be in a fully cured stage state (C-stage state) or a partially cured stage state (B-stage state). In some embodiments, the first reflective layers 208 in the B-stage state may have better adhesion with the B-stage light-transmitting layer 206 (see FIG. 3).

In some embodiments, the first reflective layers 208 may be formed on the first carrier 202 through coating or other methods. Specifically, a steel plate or steel film (not shown) with a plurality of holes is placed on the first carrier 202, and the material for the first reflective layers 208 is coated (e.g., dispensed) to fill these holes. Upon removal of the steel plate or steel film, the remaining material on the first carrier 202 forms a plurality of first reflective layers 208.

Referring to FIG. 3, in one embodiment, the first carrier 202 is flipped so that the first reflective layers 208 are laminated 310 toward a front surface 206F of the B-stage light-transmitting layer 206, such that the first reflective layers 208 are in direct contact with the B-stage light-transmitting layer 206. The term “flipped” as used herein refer to turning the first carrier 202 upside down, meaning the surface of the first carrier 202 that faces upward in FIG. 2 becomes the downward-facing after flipping. It should be noted that the planarization process in existing packaging technology for LEDs can be omitted before laminating 310 the first reflective layers 208 onto the B-stage light-transmissible layer 206. This is because the B-stage light-transmissible layer 206 has a flat front surface 206F, meeting the requirement for surface flatness.

In some embodiments, the B-stage light-transmissible layer 206 may be organic glue, inorganic glue, or a mixture thereof in any proportion, such as silicone, epoxy resin, fluorine glue, etc. In one embodiment, the material of the B-stage light-transmitting layer 206 may be silicone or epoxy resin. In some embodiments, the thickness of the B-stage light-transmitting layer 206 ranges from 150 to 400 μm (e.g., 350 μm), but the present disclosure is not limited thereto. Generally, using a thicker B-stage light-transmitting layer 206 results in better surface light emission uniformity of the light-emitting device 300, while a thinner B-stage light-transmitting layer 206 is conducive to the lightweighting of the product.

In some embodiments, any suitable molding process (e.g., vacuum lamination) may be used to laminate 310 the first reflective layers 208 and the B-stage light-transmitting layer 206. In some embodiments, the lamination 310 is conducted under a pressure of 0.1 to 1 MPa (e.g., 0.1 MPa) for a duration of 2 to 5 minutes (e.g., 3 minutes).

As shown in FIG. 4, in one embodiment, the present disclosure provides a hybrid encapsulation film 200, which may include a B-stage light-transmitting layer 206 having a front surface 206F and a back surface 206B, and a plurality of first reflective layers 208 disposed at intervals on the front surface 206F of the B-stage light-transmitting layer 206. In some embodiments, the hybrid encapsulation film 200 further includes a first carrier 202.

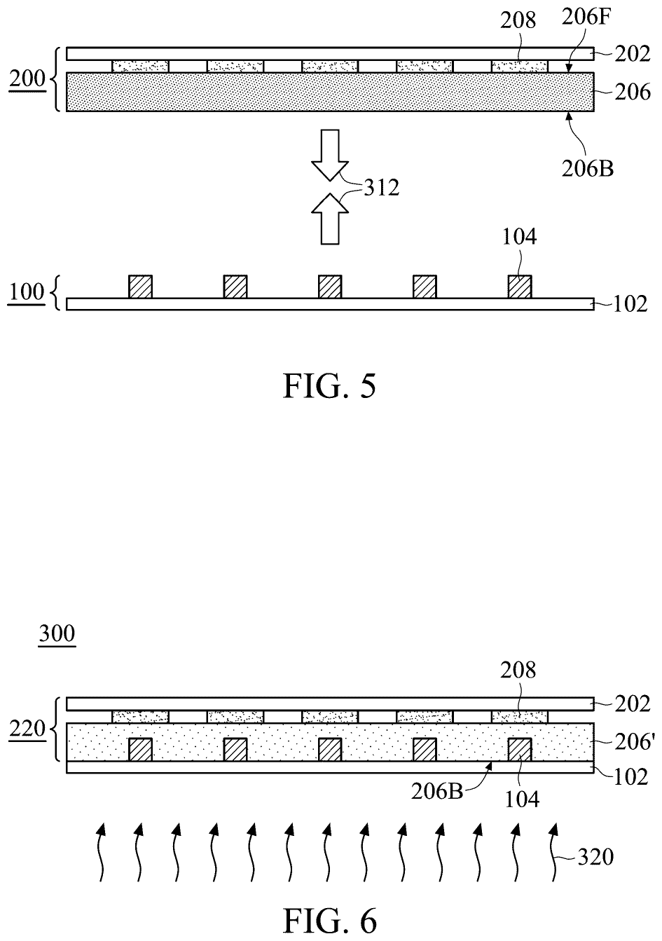

Referring to FIGS. 5 and 6, in one embodiment, the back surface 206B of the B-stage light-transmitting layer 206 of the hybrid encapsulation film 200 is laminated 310 towards the light-emitting diodes 104 of the light-emitting structure 100 (as shown in FIG. 5). This results in embedding of the light-emitting diodes 104 in the B-stage light-transmitting layer 206, where they respectively correspond to the positions of the first reflective layers 208 (as shown in FIG. 6). In some embodiments, vacuum lamination or other suitable lamination processes may be used for lamination 312. In some embodiments, the lamination 312 is conducted under a pressure of 0.05 to 1 MPa (e.g., 0.2 MPa) for a duration of 2 to 5 minutes (e.g., 3 minutes).

Still referring to FIG. 6, in one embodiment, a thermal process 320 is performed to cure the B-stage light-transmitting layer 206, thus transforming it into a C-stage light-transmitting layer 206′. In some embodiments, the thermal process 320 is carried out at a temperature of 130 to 170° C. (e.g., 140° C., 150° C., or 160° C.) for a duration of 0.5 to 5 hours (e.g., 3 hours). The term “cure,” as used herein, means that the conversion of the B-stage light-transmissible layer 206 from a B-stage state to a C-stage state through heating. In one embodiment, performing the thermal process 320 may further include curing the first reflective layers 208. In other words, in the embodiment where the first reflective layers 208 are in a B-stage state, the thermal process 320 converts the first reflective layers 208 from the B-stage state to the C-stage state. It should be understood that the thermal process 320 does not substantially affect the light-emitting efficiency and reliability of the light-emitting diodes 104.

FIG. 7A illustrates a plan view of a light-emitting device 300, in accordance with some embodiments. FIG. 7B illustrates a cross-sectional view of the light-emitting device 300, of FIG. 7A, taken along line A-A, in accordance with some embodiments. In one embodiment, the first carrier 202 is removed. As mentioned above, the first carrier 202 having a release film is easy to peel off from the surface of the first reflective layers 208.

Referring to FIG. 7A, twenty (20) light-emitting diodes 104 are arranged in an array on the substrate 102, and the same number and array of the first reflective layers 208 are also positioned above the light-emitting diodes 104, but the present disclosure is not limited thereto. In alternative embodiments, any number of the light-emitting diodes 104 can be arranged on the substrate 102 according to design requirements, and the corresponding first reflective layers 208 are provided in the same number and configuration above them. It should be noted that although the first reflective layers 208 are depicted as circular in FIG. 7A, the present disclosure is not limited thereto. In other embodiments, the first reflective layers 208 may adopt a square, polygonal, or any other suitable shape.

Referring to FIG. 7B, in some embodiments, a portion of the light emitted from the light-emitting diodes 104 passes through the first reflective layers 208, while the remainder is reflected by the first reflective layers 208 toward the C-stage light-transmitting layer 206′, as shown in the light paths L1. This arrangement reduces the light emitted upwards from the light-emitting diodes 104, thereby increasing its light path within the C-stage light-transmitting layer 206′, and improving the surface light emission uniformity of the light-emitting device 300.

In the embodiment of the present disclosure, the B-stage light-transmitting layer 206 and the first reflective layers 208 provided are laminated onto the light-emitting structure 100 in the form of a hybrid encapsulation film 200. Stated another way, the ability to simultaneously apply the B-stage light-transmitting layer 206 and the first reflective layers 208 simplifies the process and shortens the processing time, thereby increasing productivity and reducing costs. Moreover, the need for a dam around the light-emitting diodes 104 in the light-emitting device 300 is eliminated with the B-stage light-transmitting layer 206 and the first reflective layers 208 due to its low fluidity, further simplifying the process and reducing costs. Furthermore, using the hybrid encapsulation film 200 provided by the present disclosure can mitigate the issue of high drop rates of the encapsulant in existing LEDs packaging technologies, thereby lowering costs.

Some variations of the embodiments are described below. In the different drawings and illustrated embodiments, the same or similar reference numbers are used to designate the same or similar components.

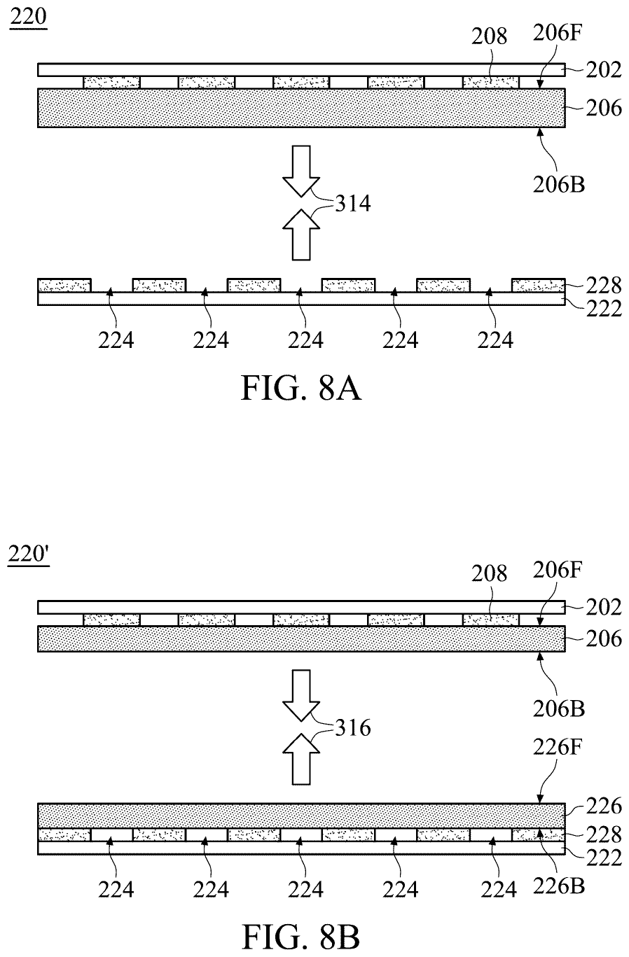

FIGS. 8-10, including FIGS. 8A and 8B, respectively illustrate cross-sectional views of various stages of manufacturing a light-emitting device 400 using a hybrid encapsulation film 200, 200′ with a second reflective layer 228, in accordance with some other embodiments. It should be noted that the features between the various embodiments can be combined and used arbitrarily as long as they do not violate or conflict the spirit of the present disclosure. Additionally, it should be understood that additional operations can be provided before, during, and after operations/processes in FIGS. 8-12, and some of the operations described below can be replaced or eliminated for additional embodiments of the method. The order of the operations/processes may be unrestricted and interchangeable.

In some embodiments, FIG. 8A follows the steps illustrated in FIG. 4, but before the steps illustrated in FIG. 11, which involve laminating 318 the hybrid encapsulation film 220 onto the light-emitting structure 100. Referring to FIG. 8A, in one embodiment, a second carrier 222 is provided, and a second reflective layer 228 is formed thereon. The second reflective layer 228 has a plurality of openings 224 that respectively correspond to the first reflective layers 208.

In some embodiments, the second carrier 222 may include a release film, with an anti-adhesive property, which prevents the release film from adhering to the second reflective layers 228. Conversely, the anti-adhesive property also facilitates the removal of the second carrier 222 from the second reflective layers 228 after curing (e.g., the curing processing 320 illustrated in FIG. 11).

In some embodiments, as mentioned above, the first reflective layers 208 can reflect light emitted from the light-emitting diodes 104 upward. The second reflective layer 228 can reflect the light emitted from the side surfaces of the light-emitting diodes 104, thereby improving the surface light emission uniformity of the light-emitting device. Further details will be discussed later, in conjunction with FIG. 13.

In one embodiment, the material, thickness, and the reflectivity of the second reflective layer 228 for the light-emitting wavelength of the light-emitting diodes 104 are similar to those of the first reflective layers 208 described in FIG. 2, and their descriptions will not be repeated herein for brevity. In one embodiment, the second reflective layer 228 may be in a C-stage state or a B-stage state. In some embodiments, the second reflective layer 228 in the B-stage state may have better adhesion with the B-stage light-transmitting layer 206, while using the second reflective layer 228 in the C-stage state can reduce costs.

In some embodiments, the thickness of the second reflective layer 228 is in the range of 40 to 80 μm (for example, 50 μm), but the present disclosure is not limited thereto. Generally, using a thicker second reflective layer 228 results in a better reflective effect, while a thinner second reflective layer 228 is conducive to controlling the light emitted from the light-emitting diodes 104.

In some embodiments, as illustrated in FIG. 8A, the second reflective layer 228 has a plurality of openings 224, and the number and arrangement of the openings 224 on the second carrier 222 are the same as those of the first reflective layers 208 after flipping the first carrier 202. Therefore, the number and arrangement of the openings 224 correspond to those of the light-emitting diodes 104. In some embodiments, each opening 224 has a width ranging from 2.5 to 4.5 cm (e.g., 3 cm), and they are spaced apart from each other in the range of 4 to 8 mm. (e.g., 6 mm), but the present disclosure is not limited thereto. As long as the light-emitting diodes 104 can be embedded in the B-stage light-transmitting layer 206 after subsequent lamination 318 (see FIG. 11) of the hybrid encapsulation film 220 and the light-emitting structure 100.

In some embodiments, the opening 224 may be circular, square, polygonal or any other suitable shape in a plan view, as shown in FIG. 7A. In some embodiments, the pattern of first reflective layers 208 may complement the pattern of second reflective layer 228. For example, in an embodiment where the first reflective layers 208 are circular, the second reflective layer 228 may have circular openings 224 pattern with a corresponding pattern.

In some embodiments, the step of providing the second reflective layer 228 may include coating the second reflective layer material onto the second carrier 222, followed by curing, and subsequently removing a portion of the second reflective layer material by drilling holes to form a second reflective layer 228 with a plurality of openings 224. In some embodiments, the second reflective layer 228 with a plurality of openings 224 can be fabricated using a mold in advance and then placed onto the second carrier 222.

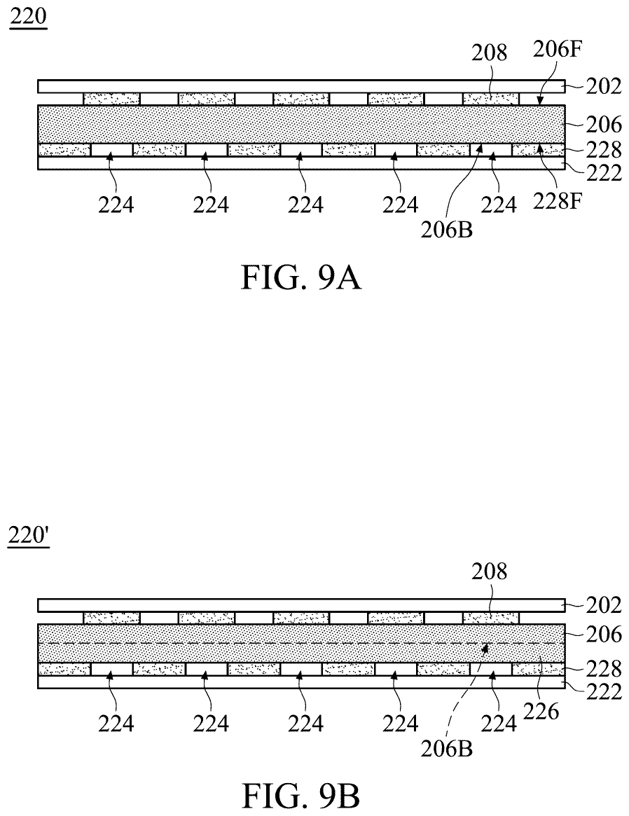

Still referring to FIG. 8A, in one embodiment, laminating 314 the second reflective layer 228 toward the back surface 206B of the B-stage light-transmitting layer 206, with the openings 224 respectively correspond to the positions of the first reflective layers 208, to form the hybrid encapsulation film 220 depicted in FIG. 9A. In some embodiments, the process conditions for laminating 314 are similar to those for laminating 310 described in FIG. 3, although they may be the same or different.

The hybrid encapsulation film 220 depicted in FIG. 9A is similar to the hybrid encapsulation film 200 depicted in FIG. 4, except that the hybrid encapsulation film 220 further includes a second reflective layer 228 disposed on the back surface 206B of the B-stage light-transmitting layer 206. In some embodiments, the hybrid encapsulation film 220 may include the second carrier 222. In some embodiments, the front surface 228F of the second reflective layer 228 is co-planar with the back surface 206B of the B-stage light-transmitting layer 206.

In other embodiments, as shown in FIG. 8B, the step of laminating the second reflective layer 228 toward the back surface 206B of the B-stage light-transmitting layer 206 includes the following: providing an additional B-stage light-transmitting layer 226 having a first surface 226F and a second surface 226B opposite to each other (where the first surface 226F may serve as its front surface and the second surface 226B may serve as its back surface); laminating the second reflective layer 228 to the second surface 226B of the additional B-stage light-transmitting layer 226; and laminating 316 the first surface 226F of the additional B-stage light-transmitting layer 226 toward the back surface 206B of the B-stage light-transmitting layer 206. The said process results in the hybrid encapsulation film 220′ depicted in FIG. 9B. Similarly, the process conditions for laminating 316 are similar to those for laminating 310 described in FIG. 3.

The hybrid encapsulation film 220′ depicted in FIG. 9B is similar to the hybrid encapsulation film 220 depicted in FIG. 9A, except that the hybrid encapsulation film 220′ further includes an additional B-stage light-transmitting layer 226 sandwiched between the B-stage light-transmitting layer 206 and the second reflective layer 228. In some embodiments, the material of the additional B-stage light-transmitting layer 226 is different from that of the B-stage light-transmitting layer 206. Thus, there is a clear interface between the additional B-stage light-transmitting layer 226 and the B-stage light-transmitting layer 206. In other embodiments, the material of the additional B-stage light-transmitting layer 226 is the same as that of the B-stage light-transmitting layer 206. Therefore, there is no obvious interface between the additional B-stage light-transmitting layer 226 and the B-stage light-transmitting layers 206, resulting in a continuous structure (not shown).

In some embodiments, the additional B-stage light-transmitting layer 226 is used for bonding with the B-stage light-transmitting layer 206. In some embodiments, the material, thickness, and the manufacturing process of the additional B-stage light-transmitting layer 226 are similar to those of the B-stage light-transmitting layer 206 described in FIG. 3, and their descriptions will not be repeated herein for brevity. In some embodiments, disparities between the additional B-stage light-transmitting layer 226 and the B-stage light-transmitting layer 206 can yield a brightness enhancement effect.

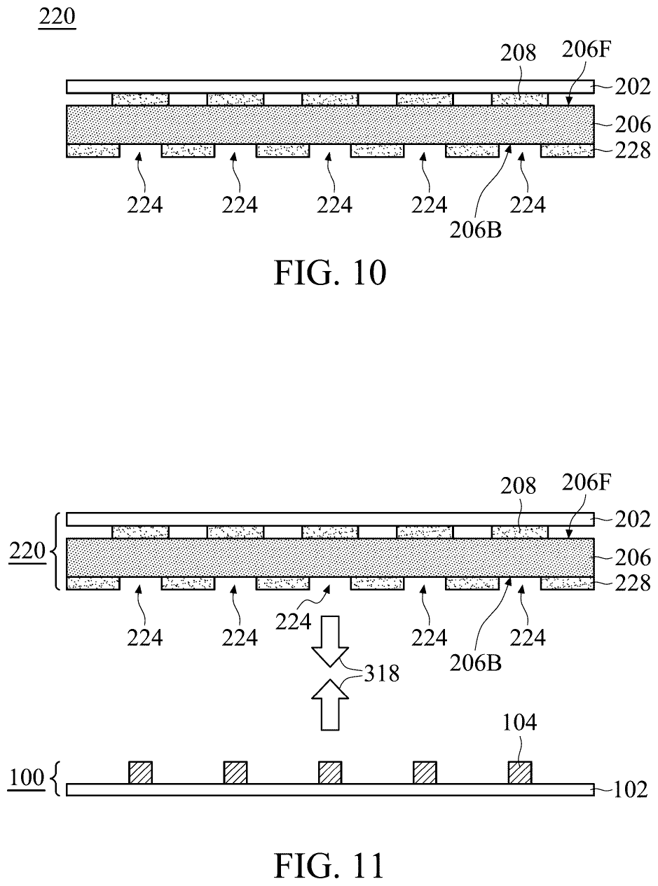

FIG. 10 follows the steps illustrated in FIG. 9A or 9B. In one embodiment, the second carrier 222 is removed. As mentioned above, the second carrier 222 having a release film is easy to peel off from the surface of the second reflective layer 228.

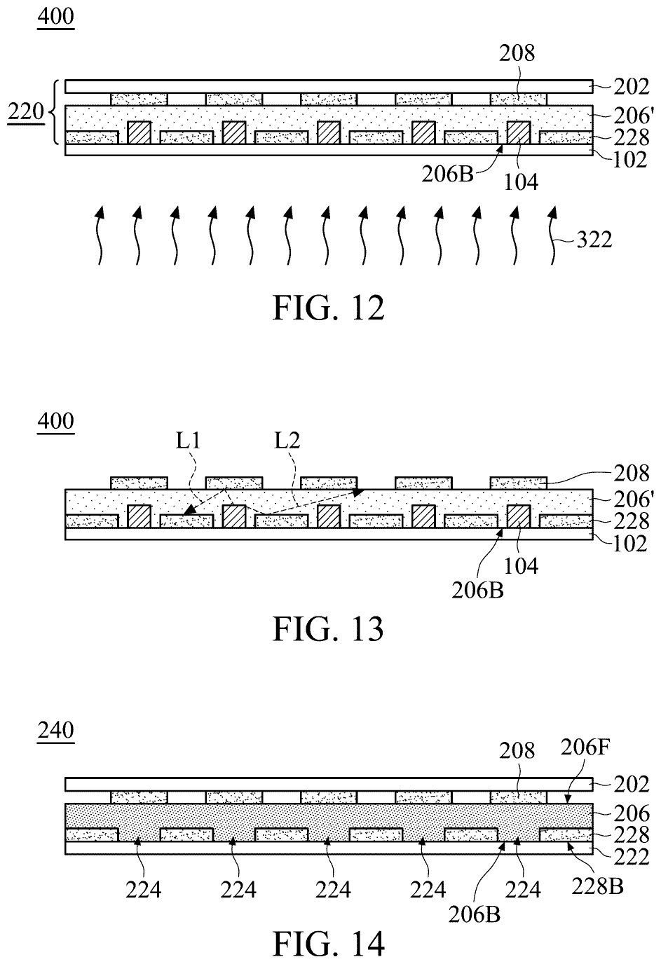

Referring to FIGS. 11 and 12, in one embodiment, the openings 224 of the second reflective layer 228 of the hybrid encapsulation film 220 are aligned with the light-emitting diodes 104 of the light-emitting structure 100, respectively. Subsequently, the exposed back surface 206B of the B-stage light-transmitting layer 206 is laminated toward the light-emitting diodes 104 (as shown in FIG. 11), so that the light-emitting diodes 104 surrounded by the second reflective layers 228 are embedded in the B-stage light-transmitting layer 206 and correspond to the positions of the first reflective layers 208 (as shown in FIG. 12).

Still referring to FIG. 12, in one embodiment, a thermal process 322 is performed on the hybrid encapsulation film 220 to cure the B-stage light-transmitting layer 206, thus transforming it into a C-stage light-transmitting layer 206′. In one embodiment, performing the thermal process 322 may further include curing the additional B-stage light-transmitting layer 206. The term “cure,” as used herein, means that the conversion of the B-stage light-transmitting layer 206 and/or the additional B-stage light-transmitting layer 206 from a B-stage state to a C-stage state through heating. In some embodiments, the process conditions for laminating 322 are similar to those for laminating 320 described in FIG. 6, although they may be the same or different.

In one embodiment, performing the thermal process 322 may further include curing the first reflective layers 208 and/or the second reflective layers 228. In other words, the thermal process 322 converts the first reflective layers 208 and/or the second reflective layers 228 from the B-stage state to the C-stage state.

Referring to FIG. 13, in one embodiment, the first carrier 202 is removed. In some embodiments, the light emitted from the top surface of the light-emitting diodes 104 is reflected by the first reflective layers 208 above the light-emitting diodes 104 toward the C-stage light-transmitting layer 206′, as shown in the light path L1. This arrangement reduces the brightness of light emitted upwards from the light-emitting diodes 104, thereby improving the surface light emission uniformity of the light-emitting device 400. In some embodiments, the light emitted from the side surfaces is reflected upward through the second reflective layers 228 between the light-emitting diodes 104, as shown in the light path L2, to further improve the surface light emission uniformity of the light-emitting device 400.

FIGS. 14-18 respectively illustrate cross-sectional views of various stages of manufacturing a light-emitting device 400 using a hybrid encapsulation film 240, in accordance with some further embodiments.

In this embodiment, FIGS. 14-18 follow the steps illustrated in FIG. 8A. The difference from the previous embodiment is that the B-stage light-transmitting layer 206 fills the openings 224 of the second reflective layer 228 during the lamination step in FIG. 8A, thus the second reflective layer 228 is embedded in the B-stage light-transmitting layer 206. This arrangement contributes to the lightweighting of the product. As shown in FIG. 14, in some embodiments, the back surface 228B of the second reflective layer 228 is co-planar with the back surface 206B of the B-stage light-transmitting layer 206 due to the second reflective layer 228 being embedded in the B-stage light-transmitting layer 206.

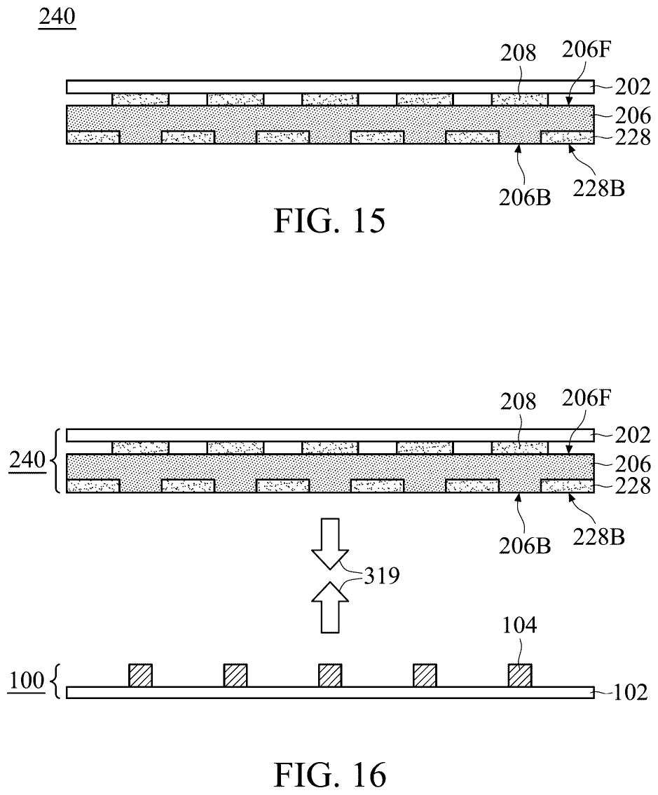

Next, referring to FIG. 15, the second carrier 222 is removed to expose the back surface 206B of the B-stage light-transmitting layer 206 and the second reflective layer 228.

Referring to FIG. 16, in some embodiments, the exposed back surface 206B of the B-stage light-transmitting layer 206 is laminated 319 toward the light-emitting diodes 104. In some embodiments, the process conditions for laminating 319 are similar to those for laminating 312 described in FIG. 5, although they may be the same or different.

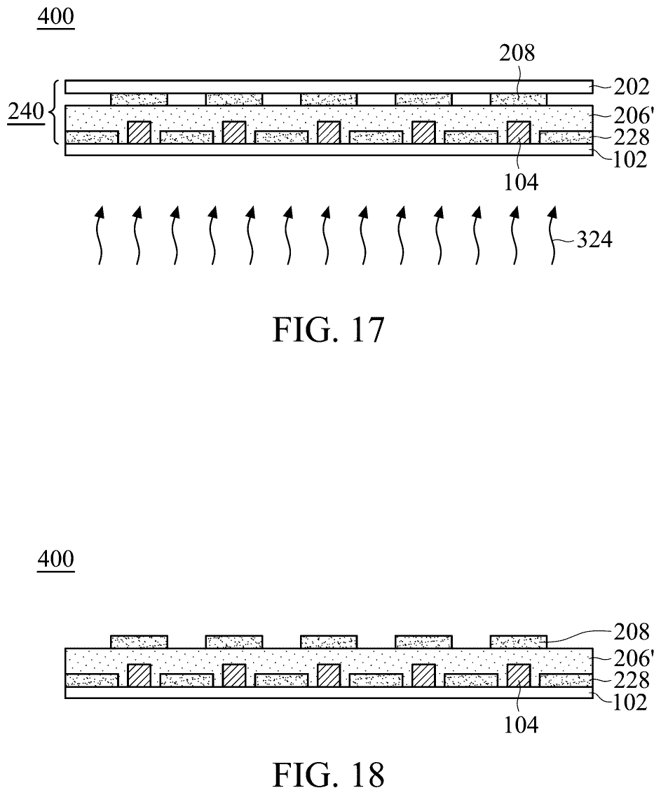

Referring to FIG. 17, in this embodiment, a thermal process 324 is performed to cure the B-stage light-transmitting layer 206, thus transforming it into a C-stage light-transmitting layer 206′. The term “cure,” as used herein, means that the conversion of the B-stage light-transmissible layer 206 from a B-stage state to a C-stage state through heating. In some embodiments, the process conditions for thermal process 324 are similar to those for thermal process 320 described in FIG. 6. Subsequently the first carrier 202 is removed, resulting in the light-emitting structure 400 depicted in FIG. 18.

The present disclosure provides hybrid encapsulation films and a method of manufacturing light-emitting devices using the same. The B-stage light-transmitting layer and the first reflective layer provided by the present disclosure are laminated onto the light-emitting structure in the form of a hybrid encapsulation film. Stated another way, the ability to simultaneously apply the encapsulation film (e.g., the B-stage light-transmitting layer) and the reflective layer (e.g., the first reflective layer) simplifies the process and shortens processing time, thereby increasing productivity and reducing costs. Moreover, the need for a dam around the LEDs is eliminated with the hybrid encapsulation film provided by the present disclosure due to its low fluidity, further simplifying the process and reducing costs. Furthermore, using the hybrid encapsulation film provided by the present disclosure can mitigate the issue of high drop rates of the encapsulant in existing LED packaging technologies, thereby lowering costs.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of manufacturing a light-emitting device, comprising:
providing a substrate;
providing a light-emitting structure comprising a plurality of solid-state light sources disposed on the substrate; and
providing a hybrid encapsulation film for encapsulating the light-emitting structure, wherein the hybrid encapsulation film comprises:
a B-stage light-transmitting layer having a front surface and a back surface; and
a plurality of first reflective layers disposed at intervals on the front surface of the B-stage light-transmitting layer;
laminating the back surface of the B-stage light-transmitting layer of the hybrid encapsulation film toward the solid-state light sources of the light-emitting structure, so that the solid-state light sources are embedded in the B-stage light-transmitting layer and respectively correspond to positions of the first reflective layers; and
performing a thermal process to cure the B-stage light-transmitting layer.

2. The method of claim 1, wherein the step of providing the hybrid encapsulation film comprises:
providing a first carrier;
disposing the first reflective layers on the first carrier at intervals, wherein the first reflective layers are in a C-stage state or a B-stage state; and
flipping the first carrier so that the first reflective layers are laminated toward the front surface of the B-stage light-transmitting layer, such that the first reflective layers are in direct contact with the B-stage light-transmitting layer.

3. The method of claim 1, wherein the step of performing the thermal process comprises curing the first reflective layers.

4. The method of claim 2, further comprising removing the first carrier.

5. The method of claim 2, wherein the step of providing the first carrier comprises forming a release film on the first carrier and the first reflective layers are disposed on the release film.

6. The method of claim 1, wherein the thermal process is performed at a temperature of 130° C. to 170° C. for 0.5 hours to 5 hours.

7. The method of claim 1, wherein a transmittance of the B-stage light-transmitting layer is greater than 85% for a light-emitting wavelength of the light-emitting structure.

8. A method of manufacturing a light-emitting device, comprising:
providing a substrate;
providing a light-emitting structure comprising a plurality of solid-state light sources disposed on the substrate; and
providing a hybrid encapsulation film for encapsulating the light-emitting structure, wherein the hybrid encapsulation film comprises:
a B-stage light-transmitting layer having a front surface and a back surface;
a plurality of first reflective layers disposed at intervals on the front surface of the B-stage light-transmitting layer; and
a second reflective layer on the back surface of the B-stage light-transmitting layer, wherein the second reflective layer has a plurality of openings corresponding to positions of the first reflective layers to partially expose the back surface of the B-stage light-transmitting layer;
aligning the openings of the second reflective layer of the hybrid encapsulation film to the solid-state light sources of the light-emitting structure respectively;
laminating the exposed back surface of the B-stage light-transmitting layer toward the solid-state light sources, so that the solid-state light sources are embedded in the B-stage light-transmitting layer and respectively correspond to positions of the first reflective layers; and
performing a thermal process to cure the B-stage light-transmitting layer.

9. The method of claim 8, wherein a method of manufacturing the hybrid encapsulation film comprises:
providing a first carrier;
disposing the first reflective layers on the first carrier at intervals, wherein the first reflective layers are in a C-stage state or a B-stage state; and
flipping the first carrier so that the first reflective layers are laminated toward the front surface of the B-stage light-transmitting layer, such that the first reflective layers are in direct contact with the B-stage light-transmitting layer;
providing a second carrier;
forming the second reflective layer on the second carrier, wherein the second reflective layer is in a C-stage state or a B-stage state and has the openings; and
laminating the second reflective layer toward the back surface of the B-stage light-transmitting layer, wherein the openings respectively correspond to positions of the first reflective layers.

10. The method of claim 9, wherein the step of laminating the second reflective layer toward the back surface of the B-stage light-transmitting layer comprises filling the openings of the second reflective layer with the B-stage light-transmitting layer.

11. The method of claim 9, wherein the step of laminating the second reflective layer toward the back surface of the B-stage light-transmitting layer comprises:
providing an additional B-stage light-transmitting layer having a first surface and a second surface opposite to each other;
laminating the second reflective layer to the second surface of the additional B-stage light-transmitting layer; and
laminating the first surface of the additional B-stage light-transmitting layer toward the back surface of the B-stage light-transmitting layer.

12. The method of claim 11, wherein the step of performing the thermal process comprises curing the additional B-stage light-transmitting layer, the first reflective layers, and the second reflective layer.

13. The method of claim 9, further comprising removing the first carrier and the second carrier.

14. A hybrid encapsulation film for encapsulating a light-emitting structure, comprising:
a B-stage light-transmitting layer having a front surface and a back surface; and
a plurality of first reflective layers disposed at intervals on the front surface of the B-stage light-transmitting layer, wherein the first reflective layers are in direct contact with the B-stage light-transmitting layer.

15. The hybrid encapsulation film of claim 14, wherein a material of the B-stage light-transmitting layer is silicone or epoxy resin.

16. The hybrid encapsulation film of claim 14, wherein a thickness of the B-stage light-transmitting layer is in a range of 150 μm to 400 μm.

17. The hybrid encapsulation film of claim 14, wherein the first reflective layers in a C-stage state or a B-stage state include polymer materials doped with reflective particles.

18. The hybrid encapsulation film of claim 14, further comprising a second reflective layer disposed on the back surface of the B-stage light-transmitting layer, wherein the second reflective layer has a plurality of openings corresponding to positions of the first reflective layers.

19. The hybrid encapsulation film of claim 18, wherein the second reflective layer in a C-stage state or a B-stage state include polymer materials doped with reflective particles.

20. The hybrid encapsulation film of claim 18, wherein the second reflective layer is embedded in the B-stage light-transmitting layer.
